(19) United States
(12) Patent Application Publication
(10) Pub. No.: US 2010/0000855 A1
(43) Pub. Date: Jan. 7, 2010

(54) Film Forming Apparatus and Method of Forming Film

(75) Inventors: Shinya Nakamura, Shizuoka (JP); Tadashi Morita, Ibaraki (JP); Naoki Morimoto, Shizuoka (JP)

Correspondence Address: FLOYD B. CAROTHERS;CAROTHERS AND CAROTHERS, 445 FORT PITT BOULEVARD, SUITE 200, PITTSBURGH, PA, 15219, US

(73) Assignee: ULVAC INC., Chigasaki-shi, Kanagawa (JP)

(21) Appl. No.: 12/084,842

(22) PCT Filed: Nov. 22, 2006
(86) PCT No.: PCT/JP2006/323281

§ 371 Date: Aug. 24, 2009

(30) Foreign Application Priority Data
Dec. 7, 2005 (JP) 2005-352894

(51) Int. Cl. C23C 14/34

(52) U.S. Cl. 204/192.12; 204/298.15; 204/298.09

(57) ABSTRACT

Provided is a film forming apparatus and a film forming method that are capable of enhancing film property uniformity and improving productivity. A film forming apparatus (1) according to the present invention includes substrate temperature adjustment means (heat source 10) for adjusting substrate temperature, and film formation is performed such that sputtered particles are incident on a substrate W on a rotary substrate support table (3) from an oblique direction. By thus retaining the substrate temperature constant in film formation, it is possible to reduce temperature unevenness on the substrate in film formation and to uniformize in-plane film property. Accordingly, the film property, including film thickness, crystallinity, and component composition ratio of a film formation layer can be made uniform, and it becomes possible to manufacture, with high productivity, a resistance change device having stable device characteristics with variations in device characteristics, including in-plane resistance and magnetoresistance effect, suppressed, for example.

### TECHNICAL FIELD

The present invention relates to a film forming apparatus and a method of forming a film, which are used in a process of manufacturing an electronic/semiconductor device having a multilayer structure, such as an MRAM (Magnetic Random Access Memory).

### BACKGROUND ART

As a nonvolatile memory, for example, semiconductor memories and ferroelectric memories (FRAM: Ferro electric RAM) are widely used. In recent years, however, resistance change devices such as a magnetic nonvolatile memory (MRAM), a phase change memory (PRAM: Phase Change RAM), and a CBRAM (Conductive Bridging RAM) are attracting attention as new memory devices.

The resistance change devices have a magnetic multilayer film structure, and multilayer films thereof are formed using a thin film forming process for manufacturing a semiconductor. However, the multilayer films constituting the resistance change device greatly vary in characteristics depending on a film property including film thickness, crystallinity, and component composition ratio, whereby film property control of an extremely high level is required as compared to use in a semiconductor device employed up to now.

Up to now, in producing the resistance change device, the multilayer films have been successively formed in the same apparatus without breaking vacuum, for preventing foreign substances from being mixed into the films (see Patent Document 1 below). In most cases, a sputtering method is employed as a film forming method of the multilayer films, which involves arranging a plurality of sputter cathodes within a vacuum chamber. Target materials attached to the plurality of sputter cathodes are, for example, formed of materials different in kind from one another to be distinguishably used in a lamination order, or a plurality of these are used simultaneously in film formation of a multi-component material layer having a predetermined component composition ratio.

Further, there is known a method of forming a film, involving causing sputtered particles to be incident on a surface of a substrate from an oblique direction while rotating the substrate, for enhancing in-plane film formation uniformity of the substrate (see Patent Document 2 below).

Patent Document 1: JP 2003-253439 A

Patent Document 2: JP 2002-167661 A

### DISCLOSURE OF THE INVENTION

### Problems to be Solved by the Invention

However, by only the film forming method which involves causing the sputtered particles to be incident on the substrate from the oblique direction while rotating the substrate, there is a problem in that crystallinity and the component composition ratio vary at different positions in the plane and that variation is caused between substrates due to temperature unevenness generated in the substrate in a radial direction. The temperature unevenness is attributable to a change in in-chamber temperature caused by continuation of a film forming process, a change of a plasma formation region to which the target is to be sputtered due to relative positional relationship between the target in use and the substrate, and the like.

Therefore, because film property uniformity cannot be obtained regarding the composition ratio, crystallinity, and the like of a film within a plane of the substrate or between the substrates by the conventional method, lowering of reliability and deterioration in yield due to the variations in device characteristics such as in-plane resistance have become a large problem.

In addition, manufacturing of the resistance change device requires a process of performing crystallization heat treatment of the multilayer films for improvement of characteristics thereof. In the related art, the heat treatment is performed after the production of the multilayer films, which additionally requires a heat treatment process after film formation, resulting in a problem in that productivity cannot be improved.

The present invention has been made in view of the above-mentioned problems, and it is therefore an object of the present invention to provide a film forming apparatus and a film forming method which are capable of enhancing film property uniformity and improving productivity.

### Means for Solving the Problems

To solve the above-mentioned problems, according to the present invention, there is provided a film forming apparatus including a vacuum chamber, a substrate support table, a substrate rotation mechanism, a sputter cathode, and substrate temperature adjustment means. The substrate support table is disposed inside the vacuum chamber. The substrate rotation mechanism causes the substrate support table to rotate. The sputter cathode is mounted with a sputter target and causes sputtered particles to be incident on a substrate on the substrate support table from an oblique direction. The substrate temperature adjustment means adjusts substrate temperature.

Further, according to the present invention, there is provided a film forming method including causing sputtered particles to be incident on a substrate on a rotary substrate support table from an oblique direction to thereby form a film. In the method, the film is formed while substrate temperature is kept constant on the substrate support table.

As described above, in the present invention, by providing the substrate temperature adjustment means for adjusting the substrate temperature and maintaining the substrate temperature constant at the time of film formation, temperature unevenness on the substrate at the time of film formation is reduced and the in-plane film property is made uniform. Thus, uniformity in film property such as film thickness, crystallinity, and component composition ratio of the film formation layer is obtained, and it becomes possible to manufacture, with high productivity, a resistance change device having stable device characteristics with variations in device characteristics, including in-plane resistance or magnetoresistance effect, suppressed, for example.

Moreover, by setting the substrate temperature to the crystallization temperature of the film formation material by the substrate temperature adjustment means, it becomes possible to perform the film formation process and the film crystallization at the same time, whereby productivity can be further improved since the crystallization heat treatment after the multilayer film formation becomes unnecessary. Also in this case, because in-plane crystallization temperature of the substrate can be kept uniform, it becomes possible to stably produce a resistance change device having desired device characteristics with in-plane crystallinity variations suppressed.

The substrate temperature adjustment means is not limited to the mechanism described above as long as it can maintain the in-plane temperature uniform without generating in-plane temperature distribution in the substrate. A hotplate having a heat source incorporated therein is preferable as the substrate support table. Note that the substrate temperature adjustment means is not limited to the heat source and may be a cooling source.

For effective adjustment of the substrate temperature by using the hotplate, it is more preferable if a structure in which the entire surface of the substrate can be attached to the substrate support table is additionally provided. Preferably, an electrostatic chuck mechanism is provided to the substrate support table.

Not just one kind, but a plurality of kinds of sputter cathodes (targets) can be arranged. The plurality of sputter cathodes are, for example, formed of materials different in kind from one another to be distinguishably used in a lamination order, or the plurality of those are used simultaneously in film formation of a multi-component material layer having a predetermined component composition ratio. In particular, according to the present invention, because the substrate temperature can be kept uniform in the plane, it becomes possible to stably produce a resistance change device having desired device characteristics with in-plane variations of the component composition ratio suppressed.

### EFFECT OF THE INVENTION

As described above, according to the present invention, the film property including film thickness, crystallinity, and component composition ratio of the film formation layer can be kept uniform in the plane. Thus, it becomes possible to manufacture, with high productivity, a resistance change device having stable device characteristics with variations in device characteristics, including in-plane resistance or magnetoresistance effect, suppressed, for example.

### BRIEF DESCRIPTION OF THE DRAWINGS

FIG. 1 is a schematic sectional view of a film forming apparatus 1 according to an embodiment of the present invention.

FIG. 2 is a schematic plan view of the film forming apparatus 1.

FIG. 3 graphically shows experimental results of inter-substrate temperature distribution, for illustrating an operation of the film forming apparatus 1.

FIG. 4 is a schematic structural view of a vacuum processing apparatus equipped with the film forming apparatus according to the present invention.

### DESCRIPTION OF SYMBOLS

1 film forming apparatus
2 vacuum chamber
3 substrate support table
4 rotation axis
5A-5C sputter cathode
6 processing chamber
7 pedestal
9 driving source
10 heat source (substrate temperature adjustment means)
11 electrostatic chuck electrode
14 shutter mechanism
20 vacuum processing apparatus
W substrate

### BEST MODE FOR CARRYING OUT THE INVENTION

Hereinafter, an embodiment of the present invention will be described with reference to the drawings. Note that the present invention is not limited to the following embodiment and can be variously modified based on the technical spirit of the present invention.

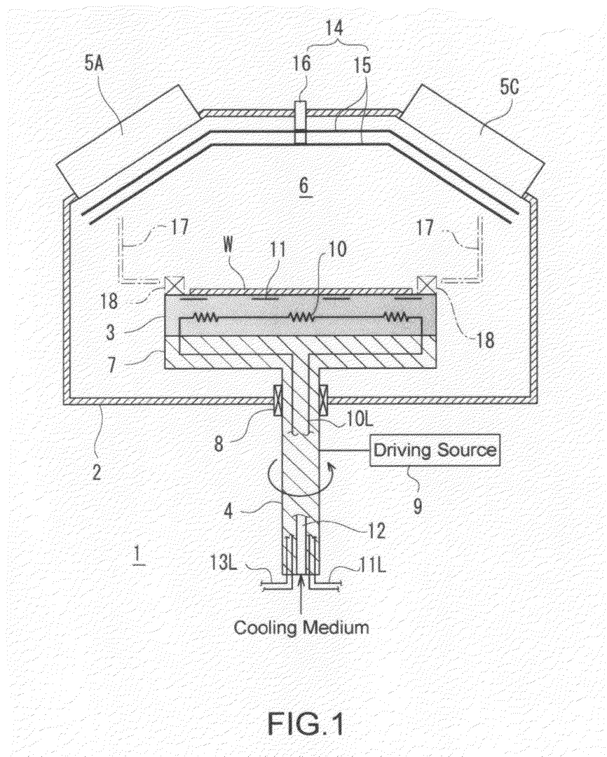

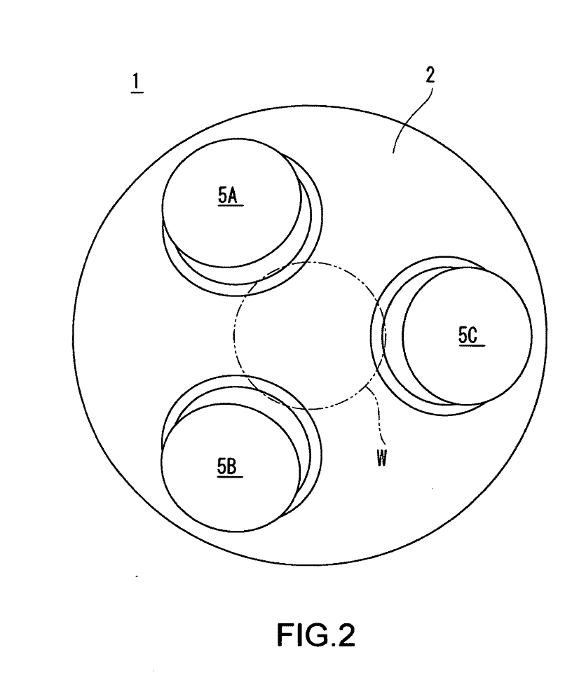

FIGS. 1 and 2 are schematic structural views of a film forming apparatus 1 according to the embodiment of the present invention. In this embodiment, the film forming apparatus 1 is constituted as a magnetron sputtering apparatus.

The film forming apparatus 1 includes a vacuum chamber 2, a substrate support table 3 disposed inside the vacuum chamber 2, a substrate rotation mechanism for rotating the substrate support table 3 around a rotation axis 4, and a plurality of (3 in this embodiment) sputter cathodes 5A, 5B, and 5C provided inside the vacuum chamber 2.

The vacuum chamber 2 has a processing chamber 6 defined inside, which is capable of being pressure-reduced to a predetermined vacuum degree via vacuum exhaust means (not shown). Further, the vacuum chamber 2 has at a predetermined position thereof a gas introduction nozzle (not shown) for introducing process gas such as argon gas or reactive gas such as oxygen and nitrogen into the processing chamber 6.

The substrate support table 3 is composed of a hotplate with a heat source 10 incorporated therein. The heat source 10 is provided as temperature adjustment means for heating a substrate W mounted on the substrate support table 3 to a predetermined temperature. For example, the heat source 10 retains the substrate W at a certain temperature within a range of 20° C. to 500° C. Note that the heat source 10 employs resistance heating.

The substrate support table 3 is made of an insulation material (e.g., PBN: pyrolytic boron nitride), and an appropriate number of electrostatic chuck electrodes 11 are provided at appropriate positions inside the substrate support table 3 in the vicinity of a surface thereof. Accordingly, the substrate W is brought into close contact with the surface of the substrate support table 3 to thereby make the in-plane substrate temperature uniform. Note that a semiconductor substrate such as a silicon substrate is used as the substrate W, for example.

The substrate support table 3 is mounted on a pedestal 7 made of metal (e.g., aluminum). A rotation axis 4 is fixed to the pedestal 7 at a center of a bottom surface thereof. The pedestal 7 is structured to be rotatable via a driving source 9 such as a motor. A substrate rotation mechanism for causing the substrate W to rotate around the center thereof is thus structured. Note that the rotation axis 4 is fixed to the vacuum chamber 2 via a bearing mechanism (not shown) and a seal mechanism such as magnetic fluid sealing 8.

Although not shown, the pedestal 7 has a cooling jacket for circulation of a cooling medium provided inside, which is structured as another specific example of the substrate temperature adjustment means for cooling the substrate support table 3 to a predetermined temperature (e.g., −40° C. to 0C). An introduction/lead-out duct line 12 for the cooling medium is disposed inside the rotation axis 4 together with heat source wiring 10L, electrostatic chuck wiring 11L, and the like. Note that temperature measurement wiring 13L connected to temperature measurement means such as a thermocouple (not shown) for measuring the temperature of the substrate support table 4 is also provided inside the rotation axis 4.

Next, as shown in FIG. 2, the sputter cathodes 5A to 5C are disposed at equiangular intervals concentrically around the substrate W at an upper portion of the vacuum chamber 2. It is assumed that each of the sputter cathodes 5A to 5C is equipped with an independent plasma generation source such as high-frequency power supply and a magnet mechanism for forming plasma within the processing chamber 6, details of which will be omitted.

Each of the sputter cathodes 5A to 5C retains a sputter target made of an arbitrary material for film formation on the substrate W. The sputter cathodes 5A to 5C are provided in the vacuum chamber 2 while being tilted by a predetermined angle so that sputter particles ejected from the target by an argon ion in plasma are incident on the substrate W from an oblique direction with respect to a normal line direction.

Specifically, in this embodiment, in forming a film by causing the sputtered particles to be incident on the substrate W mounted on the rotary substrate support table 3 from the oblique direction, by retaining the substrate temperature constant, the temperature unevenness on the substrate at the time of film formation is eliminated to realize uniformity in in-plane film property.

The targets retained by the sputter cathodes 5A to 5C are, for example, formed of materials different in kind from one another to be distinguishably used in a lamination order, or the plurality of those are used simultaneously in film formation of a ternary material layer having a predetermined component composition ratio. Note that the number of sputter cathodes to be disposed is not particularly limited, and the number may be one or plural depending on the material for the film formation.

The material constituting the target is not particularly limited, but in production of a resistance change device such as an MRAM or a PRAM, a ferromagnetic material or an anti-ferromagnetic material constituting at least one function layer of the device is appropriately used. Specific examples thereof include an Ni—Fe, Co—Fe, Pt—Mn, or Ge—Sb—Te-based material, and a Tb—Sb—Fe—Co-based material for a magneto-optical device. A target may be prepared for each of those elements to form a material layer having a desired component composition ratio by sputtering the plurality of targets at the same time, or it is also possible to use an alloy target composed of those elements.

Moreover, targets made of materials constituting an insulation layer, a protection layer, and a conductive layer in a magnetic multilayer film device may be used. For example, the target materials can be selected according to a kind of device to be produced, the materials including Cu, Ru, Ta, and Al. Further, it is possible to form an oxide film or a nitride film by introducing reaction gas such as oxygen or nitrogen.

Note that when performing film formation using a plurality of sputter cathodes, by mutually differentiating a drive frequency of the sputter cathodes by, for example, 1 kHz or more, crosstalk between the sputter cathodes can be avoided, whereby plasma can be stably formed.

Incidentally, when a plurality of sputter cathodes are provided, there is a case where an arbitrary one or not all, but a plurality of sputter cathodes are used for film formation on the substrate W using a predetermined material instead of a case where the plurality of sputter cathodes are all used at the same time. In this case, a shutter mechanism 14 is provided in the processing chamber 6 to prevent a material of a different kind from being mixed into the film formation material (contamination) due to exposure of the not-in-use sputter target to the plasma formed in the processing chamber 6.

The shutter mechanism 14 includes a plurality of shield plates 15 and a rotation axis 16 for rotating the shield plates 15 individually. Each of the shield plates 15 is composed of, for example, an umbrella-like metal plate of a size enough to cover all the sputter cathodes 5A to 5C. Each of the shield plates 15 has openings formed in advance at parts corresponding to the sputter cathodes 5A to 5C, respectively. Moreover, rotational positions of the shield plates 15 are appropriately adjusted by the driving of the rotation axis 16, whereby it is possible to select a state where all the sputter cathodes are open or a state where only an arbitrary one or two sputter target/targets is/are open. Note that the number of shield plates 15 to be arranged is not limited to that in the example shown in the figure.

In the film forming apparatus 1 according to this embodiment, deposition preventive plates 17 for preventing film formation materials from adhering to inner wall surfaces of the vacuum chamber 2 are provided inside the processing chamber 6. The deposition preventive plates 17 are movable in the vertical direction and are driven according to attachment/detachment operations of the substrate W with respect to the substrate support table 3. Further, magnets 18 for controlling a magnetization direction of the magnetic material used for the film formation on the substrate W may be appropriately disposed on a circumference of a top surface of the substrate support table 3.

In the film forming apparatus 1 according to this embodiment structured as described above, film formation is performed such that sputtered particles are incident on the substrate W placed on the rotary substrate support table 3 from an oblique direction. Accordingly, in-plane film thickness distribution can be made uniform as compared to the case where target surfaces are disposed in parallel so as to oppose each other on the substrate surface.

Furthermore, in this embodiment, film formation is performed such that the substrate W is maintained at a certain temperature (e.g., crystallization temperature) by the heat source 10. Accordingly, as compared to the film formation method of the related art in which the film formation temperature is set to room temperature, it becomes possible to suppress an influence of disturbance components such as in-chamber temperature change due to continuance of the film formation processing and plasma formation distribution inside the processing room, and to reduce temperature unevenness of the substrate W in the radial direction.

Therefore, according to this embodiment, it also becomes possible to make the film formation temperature of the material layers deposited on the substrate uniform at the same time. Thus, it is possible to stably form a material layer having large temperature dependency regarding crystallinity and component composition ratio with uniform crystallinity and component composition ratio within the substrate plane, and to obtain film property uniformity.

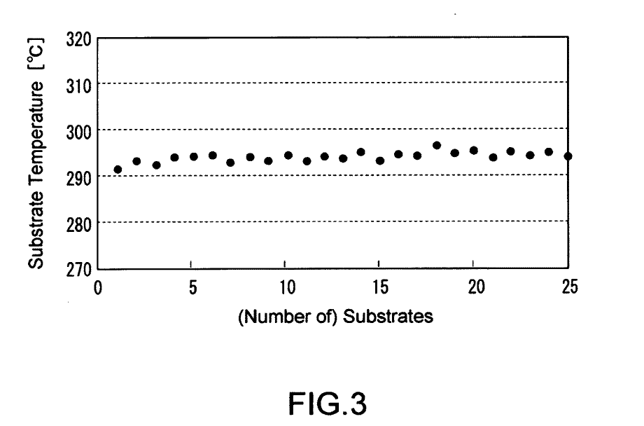

In addition, in this embodiment, not only the in-plane temperature uniformity of the substrate but also temperature uniformity between substrates can be obtained. FIG. 3 shows an example of results of an experiment conducted by the inventors of the present invention. In this experiment, measurement was made on inter-substrate temperature change when a silicon oxide film having a thickness of 100 nm is formed on the surface of the substrate having an 8-inch diameter by the film forming method of the present invention. The abscissa axis represents the number of substrate processing times and the ordinate axis represents substrate temperature. The temperature of the substrate support table was set at 300° C. As can be seen from the results shown in FIG. 3, an average substrate temperature was 293.9° C. and a temperature difference between substrates was suppressed to 6° C. or less.

As described above, according to this embodiment, it is possible to obtain inter-substrate uniformity as well as in-plane uniformity of a film property of the film formation layer on the substrate, which includes film thickness, crystallinity, and component composition ratio. Particularly in the present invention, a significant effect is obtained in film formation of a magnetic artificial lattice function layer of a resistance change device having a film thickness of 50 nm or less, and it becomes possible to stably produce a resistance change device having device characteristics, such as in-plane resistance or magnetoresistance effect. From the experiment conducted by the inventors of the present invention, upon forming a Ge—Sb—Te-based ternary magnetic layer and observing in-plane crystallinity thereof, it has been confirmed that high uniformity was obtained.

Further, according to this embodiment, it becomes possible to control the component composition ratio or crystal phase of the film formation layer on the substrate by merely adjusting the setting temperature of the substrate W (substrate support table 3), whereby film property control of the film formation layer can be easily performed as compared to the related art. Note that the same effect can also be obtained by controlling application power of the sputter cathodes 5A to 5C instead of controlling the substrate temperature.

Furthermore, according to this embodiment, by correlating the setting temperature of the substrate W (substrate support table 3) to the crystallization temperature of the film formation layer, it becomes possible to perform film formation and crystallization at the same time. Thus, crystallization heat treatment does not need to be additionally executed after the film formation, whereby it becomes possible to enhance productivity.

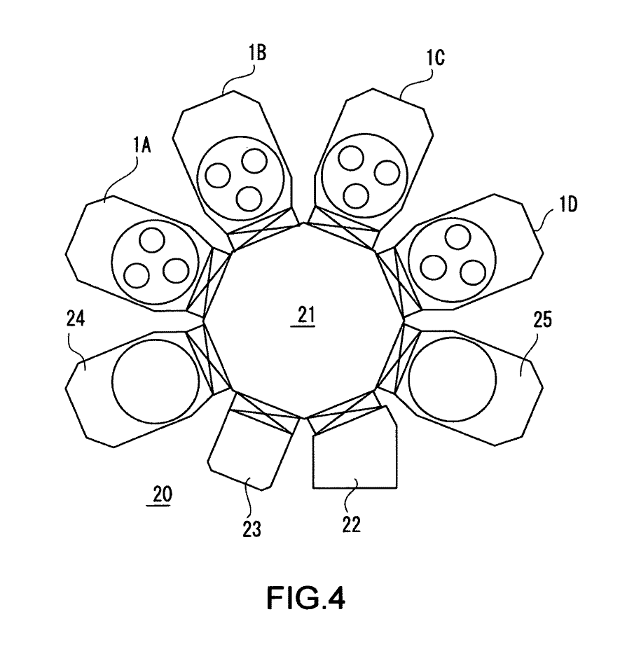

Incidentally, the resistance change device having a magnetic multilayer film structure is produced using a vacuum processing apparatus 20 schematically shown in FIG. 4, for example. The vacuum processing apparatus 20 is composed such that a plurality of processing rooms 1A, 1B, 1C, 1D, 22, 23, 24, and 25 are arranged in a cluster around a conveyor room 21 via gate valves. The conveyor room 21 is pressure-reduced to a predetermined vacuum degree, and a substrate conveyor robot (not shown) is provided inside the conveyor room 21. For example, a processing room 22 functions as a load/unload room, and a processing room 23 functions as a preliminary room for performing preprocessing (heating, cooling, and the like) before film formation. Other processing rooms function as film formation rooms. In particular, the processing rooms 1A to 1D are each composed of the film forming apparatus 1 shown in FIG. 1. Note that the number of film formation rooms to be arranged and the like is appropriately changed depending on a device structure or the kind of the film formation material.

Predetermined material layers are sequentially laminated on the substrate mounted to the vacuum processing apparatus 20 through each of the film formation rooms to thereby produce a resistance change device such as an MRAM, PRAM, and GRAM (Giant Magneto-Resistive). As described above, multilayer films are successively formed in the same vacuum processing apparatus without removing the vacuum, whereby it becomes possible to stably form high-quality films.

1. A film forming apparatus, comprising:
a vacuum chamber;
a substrate support table disposed inside the vacuum chamber;
a substrate rotation mechanism for causing said substrate support table to rotate;
a sputter cathode mounted with a sputter target, for causing sputtered particles to be sputtered incident on a substrate supported on said substrate support table from an oblique direction; and
substrate temperature adjustment means for adjusting the substrate temperature of said substrate.

2. The film forming apparatus according to claim 1, characterized in that the substrate temperature adjustment means is a heat source or a cooling source incorporated into said substrate support table.

3. The film forming apparatus according to claim 1, characterized in that said substrate support table is provided with an electrostatic chuck mechanism.

4. The film forming apparatus according to claim 1, characterized in that said sputter cathode is provided in a plurality of numbers, and an independent plasma generation source is provided to each of the plurality of said sputter cathodes.

5. The film forming apparatus according to claim 4, characterized in that a shutter mechanism for blocking an arbitrary one or plurality of said sputter cathodes is provided between the plurality of said sputter cathodes and said substrate support table.

6. The film forming apparatus according to claim 1, characterized in that said sputter cathode is formed of a magnetic material that forms at least one function layer of a resistance change device.

7. A film forming method, comprising:
causing sputtered particles to be spattered incident on a substrate positioned on a rotary substrate support table from an oblique direction to thereby form a film,
and forming the film while the substrate temperature is kept constant.

8. The film forming method according to claim 7, characterized in that the substrate temperature is set to the crystallization temperature of a film formation material.

9. The film forming method according to claim 7, characterized in that the film formation on the substrate includes applying high-frequency power to a plurality of sputter cathodes at the same time.

10. The film forming method according to claim 9, characterized in that the high-frequency power applied to the plurality of sputter cathodes is varied in power supply frequency from one to another.
